(19) United States
(12) Patent Application Publication
(10) Pub. No.: US 2026/0088089 A1
(43) Pub. Date: Mar. 26, 2026

(54) SEMICONDUCTOR DEVICE

(71) Applicant: Kioxia Corporation, Tokyo (JP)

(72) Inventors: Yutaka SHIMIZU, Yokohama Kanagawa (JP); Ryo FUKUDA, Yokohama Kanagawa (JP)

(21) Appl. No.: 19/062,974

(22) Filed: Feb. 25, 2025

(30) Foreign Application Priority Data
Sep. 20, 2024 (JP) 2024-163318

(51) Int. Cl. G11C 16/08; G11C 16/04

(52) U.S. Cl. CPC G11C 16/08; G11C 16/0483

(57) ABSTRACT

According to some embodiments, a semiconductor device includes a signal input terminal configured to input a signal. The semiconductor device includes a first transistor of a first conductivity type, a second transistor of a second conductivity type, a third transistor of the second conductivity type, a fourth transistor of the second conductivity type. The current capacity of the second transistor and a current capacity of the third transistor are higher than a current capacity of the first transistor.

### CROSS-REFERENCE TO RELATED APPLICATION

This application is based upon and claims the benefit of priority from Japanese Patent Application No. 2024-163318, filed Sep. 20, 2024, the entire contents of which are incorporated herein by reference.

### FIELD

Embodiments described herein relate generally to a semiconductor device.

### BACKGROUND

A semiconductor device is known that includes a signal input terminal configured to input a signal, and an inverter circuit having an input terminal connected to the signal input terminal. Examples of related art include US-B- 4,687,954, US-A-2019/0229714, and US-A-2016/0241220.

### DESCRIPTION OF THE DRAWINGS

FIG. 1 is a schematic block diagram illustrating a configuration of a memory system;

FIG. 2 is a schematic side view illustrating a configuration example of the memory system;

FIG. 3 is a schematic plan view illustrating the same configuration example;

FIG. 4 is a schematic block diagram illustrating a configuration of a memory die;

FIG. 5 is a schematic circuit diagram illustrating a configuration of a portion of the memory die;

FIG. 6 is a schematic perspective view illustrating a configuration of a portion of the memory die;

FIG. 7 is a schematic circuit diagram illustrating a configuration of a chip enable signal detection circuit;

FIG. 8 is a schematic graph showing operation of the chip enable signal detection circuit;

FIG. 9 is a schematic circuit diagram illustrating a configuration of the chip enable signal detection circuit;

FIG. 10 is a schematic circuit diagram illustrating a configuration of the chip enable signal detection circuit;

FIG. 11 is a schematic circuit diagram illustrating a configuration of the chip enable signal detection circuit;

FIG. 12 is a schematic circuit diagram illustrating a configuration of the chip enable signal detection circuit;

FIG. 13 is a schematic circuit diagram illustrating a configuration of a chip enable signal detection circuit according to a second embodiment; and

FIG. 14 is a schematic circuit diagram illustrating a configuration of a chip enable signal detection circuit according to a third embodiment.

### DETAILED DESCRIPTION

Embodiments provide a semiconductor device that consumes low power and operates suitably.

In general, according to one embodiment, a semiconductor device includes a signal input terminal configured to input a signal, a first transistor of a first conductivity type, a second transistor of a second conductivity type, a third transistor of the second conductivity type, and a fourth transistor of the second conductivity type. The first transistor includes a source electrode electrically connected to a first voltage supply line, a drain electrode electrically connected to a first node, and a gate electrode electrically connected to the signal input terminal. The second transistor includes a source electrode electrically connected to a second voltage supply line, a drain electrode electrically connected to a second node, and a gate electrode electrically connected to the signal input terminal. The third transistor includes a source electrode electrically connected to the second node, a drain electrode electrically connected to the first node, and a gate electrode electrically connected to the signal input terminal. The fourth transistor includes a source electrode electrically connected to the second node, a drain electrode electrically connected to the first voltage supply line, and a gate electrode to which a signal of the first node is provided as input. A current capability of the second transistor and a current capability of the third transistor are higher than a current capability of the first transistor.

Next, the semiconductor device according to the embodiments will be described in detail with reference to the drawings. The following embodiments are merely examples and are not intended to limit the present disclosure.

Also, when referred to as a “semiconductor device” in the present specification, it may refer to a semiconductor storage device, or may refer to other semiconductor devices. Also, when referred to as a “semiconductor storage device” in the present specification, it may also mean a memory die (memory chip), or a memory system including a controller die, such as a memory card, SSD, or the like. Furthermore, a semiconductor memory storage device may also mean a configuration including a host computer, such as a smartphone, a tablet terminal, a personal computer, or the like. Also, the present specification illustrates a NAND flash memory as a semiconductor storage device. However, the semiconductor storage device may be a memory other than a NAND flash memory.

Also, in the present specification, if a first configuration is said to be “electrically connected” to a second configuration, the first configuration may be directly connected to the second configuration, or the first configuration may be connected to the second configuration via wiring, a semiconductor member, a transistor, or the like. For example, if three transistors are connected in series, even if the second transistor is in the off state, the first transistor is “electrically connected” to the third transistor.

Also, in the present specification, if a first configuration is said to be “electrically connected between” a second configuration and a third configuration, it may mean that the first, second, and third configurations are connected in series, and that the second configuration is electrically connected to the third configuration via the first configuration.

Also, in the present specification, when a circuit or the like is said to “conduct” two wirings or the like, for example, this circuit or the like includes a transistor or the like, and this transistor or the like is provided in a current path between the two wirings, which may mean that this transistor or the like is in an ON state. Generally, it should be understood that any device, processing circuit, memory device, storage system, controller, computing system, networked system, and/or any other electronic apparatus and/or system described herein can be implemented using one or more processors, memory elements, integrated circuits, firmware, software, or any combination thereof.

### First Embodiment

### [Memory System 10]

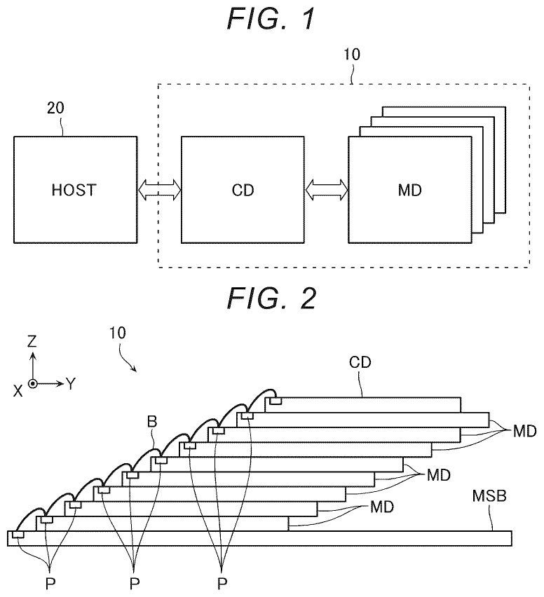

FIG. 1 is a schematic block diagram illustrating a configuration of a memory system 10.

The memory system 10 (e.g., storage device, computing system, semiconductor system, memory subsystem, or any electronic apparatus capable of data retention and processing) reads, writes, erases, and so on, user data in response to a signal transmitted from a host computer 20. The memory system 10 is a system capable of storing user data, such as a memory card, an SSD, or others. The memory system 10 includes a plurality of memory dies MD that store user data, and a controller die CD connected to the plurality of memory dies MD and the host computer 20. The controller die CD includes, for example, a processor, a RAM, or the like, and performs processing such as conversion of logical addresses and physical addresses, bit error detection/correction, garbage collection (also referred to as “compaction”), wear leveling, or the like.

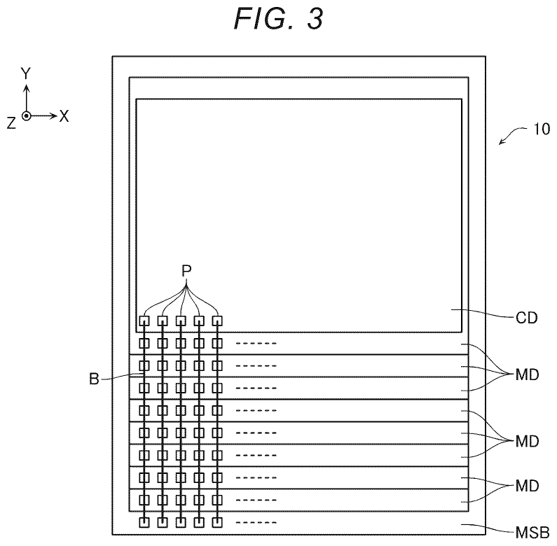

FIG. 2 is a schematic side view illustrating a configuration example of the memory system 10 according to the present embodiment. FIG. 3 is a schematic plan view illustrating the same configuration example. For the sake of explanation, some of the configurations are omitted in FIGS. 2 and 3.

As illustrated in FIG. 2, the memory system 10 according to the present embodiment includes a mounting substrate MSB, a plurality of memory dies MD stacked on the mounting substrate MSB, and a controller die CD stacked on the memory dies MD. Of the upper surface of the mounting substrate MSB, a pad electrode P is provided in the region of the end in the Y direction, and some of the other regions are adhered to the lower surface of the memory die MD through an adhesive or the like. Of the upper surface of the memory die MD, a pad electrode P is provided in the region of the end in the Y direction, and other regions are adhered to the lower surface of the other memory die MD or the controller die CD through an adhesive or the like. Of the upper surface of the controller die CD, a pad electrode P is provided in the region of the end in the Y direction.

As illustrated in FIG. 3, the mounting substrate MSB, the plurality of memory dies MD, and the controller die CD each include a plurality of pad electrodes P arranged in the X direction. The plurality of pad electrodes P provided in the mounting substrate MSB, the plurality of memory dies MD, and the controller die CD are respectively connected to each other via a bonding wire B.

The configuration illustrated in FIGS. 2 and 3 is only an example, and the specific configuration can be adjusted as appropriate. For example, in the example illustrated in FIGS. 2 and 3, the controller die CD is stacked on the plurality of memory dies MD, and these configurations are connected by the bonding wire B. In such a configuration, the plurality of memory dies MD and the controller die CD are in a single package. However, the controller die CD may be in a separate package from the memory die MD. The plurality of memory dies MD and the controller die CD may also be connected to each other via a through electrode or the like, rather than the bonding wire B.

### [Configuration of Memory Die MD]

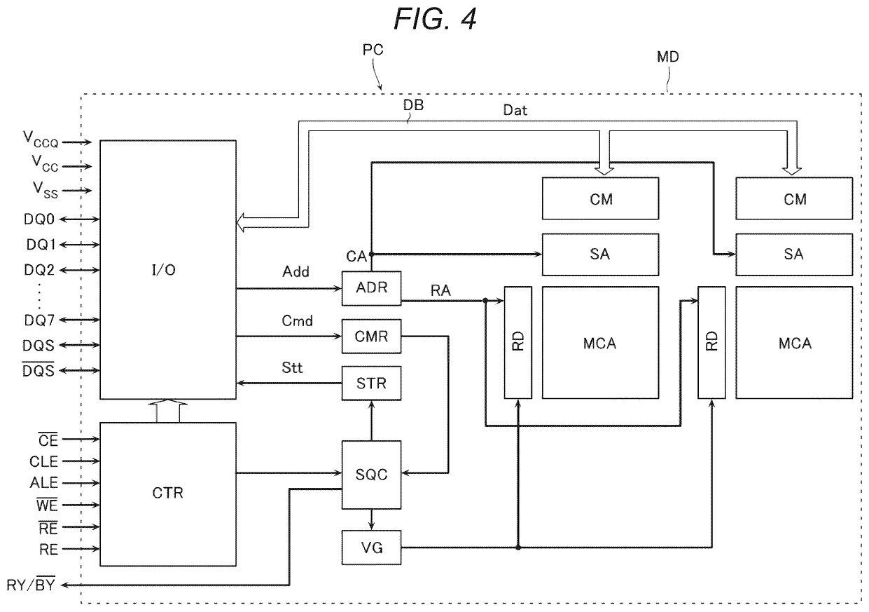

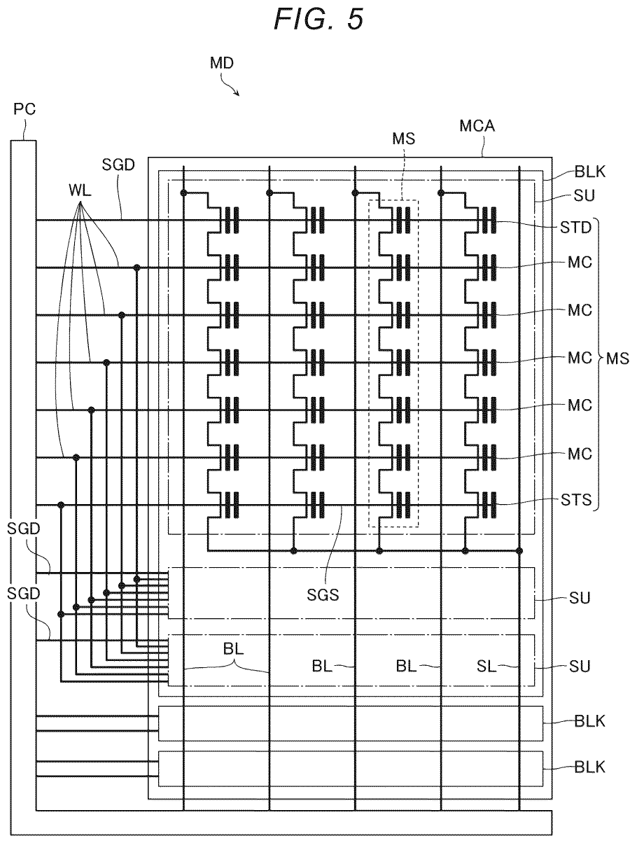

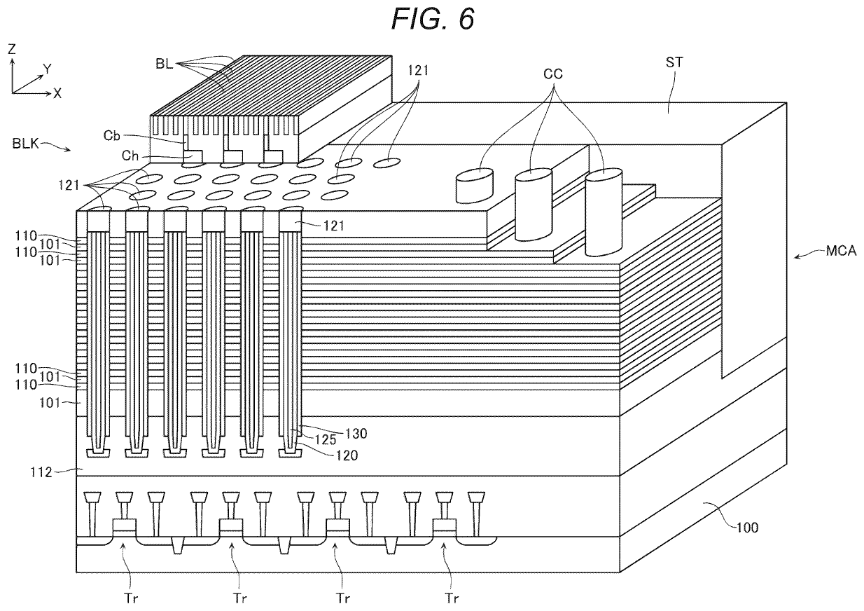

FIG. 4 is a schematic block diagram illustrating a configuration of the memory die MD according to a first embodiment. FIG. 5 is a schematic circuit diagram illustrating a configuration of a portion of the memory die MD. FIG. 6 is a schematic perspective view illustrating a configuration of a portion of the memory die MD.

FIG. 4 illustrates a plurality of control terminals and the like. The plurality of control terminals may be represented as a control terminal corresponding to the high active signal (positive logic signal), as a control terminal corresponding to the low active signal (negative logic signal), or as a control terminal corresponding to both the high active signal and the low active signal. In FIG. 4, the reference numeral of the control terminal corresponding to the low active signal includes an overline. In the present specification, the reference numeral of the control terminal corresponding to the low active signal includes a slash (“/”). The description of FIG. 4 is an example, and the specific aspects can be adjusted as appropriate. For example, some or all of the high active signals can be low active signals, and some or all of the low active signals can be high active signals.

In addition, an arrow indicating an input/output direction is illustrated next to the plurality of control terminals illustrated in FIG. 4. In FIG. 4, the control terminal with the left-to-right arrow can be used for inputting data or other signals from the controller die CD to the memory die MD. In FIG. 4, the control terminal with the right-to-left arrow can be used for outputting data or other signals from the memory die MD to the controller die CD. In FIG. 4, the control terminal with the left and right bidirectional arrows can be used for both inputting data or other signals from the controller die CD to the memory die MD and outputting data or other signals from the memory die MD to the controller die CD.

As illustrated in FIG. 4, the memory die MD includes a memory cell array MCA that stores user data, and a peripheral circuit PC connected to the memory cell array MCA.

### [Configuration of Memory Cell Array MCA]

The memory cell array MCA includes a plurality of memory blocks BLK, as illustrated in FIG. 5. The plurality of memory blocks BLK each includes a plurality of string units SU. The plurality of string units SU each includes a plurality of memory strings MS. One end of the plurality of memory strings MS is connected to the peripheral circuit PC via the bit line BL, respectively. Further, the other end of the plurality of memory strings MS is connected to the peripheral circuit PC via the common source line SL, respectively.

The memory string MS includes a drain-side select transistor STD connected in series between the bit line BL and the source line SL, a plurality of memory cells MC (memory cell transistor), and a source-side select transistor STS. Hereinafter, the drain-side select transistor STD and the source-side select transistor STS may be referred to as simply the select transistor STD, STS, and the like.

The memory cell MC is a field effect type transistor including a semiconductor layer, a gate insulating film, and a gate electrode. The semiconductor layer functions as a channel region. The gate insulating film includes a charge storage film. The threshold voltage of the memory cell MC changes according to the amount of charge in the charge storage film. The memory cell MC stores one or a plurality of bits of user data. A word line WL is connected to the gate electrode of the plurality of memory cells MC corresponding to the memory string MS. Each of the word lines WL is commonly connected to all the memory strings MS in one memory block BLK.

The select transistors STD and STS are field effect type transistors including a semiconductor layer, a gate insulating film, and a gate electrode. The semiconductor layer functions as a channel region. Select gate lines SGD and SGS are connected to the gate electrodes of the select transistors STD and STS, respectively. A drain-side select gate line SGD is provided corresponding to the string unit SU and is commonly connected to all the memory strings MS in one string unit SU. A source-side select gate line SGS is commonly connected to all the memory strings MS in the memory block BLK.

The memory cell array MCA is provided above the semiconductor substrate 100, as illustrated in FIG. 6, for example. In addition, a plurality of transistors Tr that constitute the peripheral circuit PC is provided on the upper surface of the semiconductor substrate 100. The plurality of transistors Tr each includes a channel region configured with a part of the upper surface of the semiconductor substrate 100, a gate insulating film formed on the upper surface of the semiconductor substrate 100, and a gate electrode facing the channel region through the gate insulating film.

The memory cell array MCA includes the plurality of memory blocks BLK arranged in the Y direction. In addition, an inter-block insulating layer ST such as silicon oxide (SiO₂) is provided between two adjacent memory blocks BLK in the Y direction. In addition, a plurality of bit lines BL arranged in the X direction and extending in the Y direction is provided above the memory cell array MCA.

The memory block BLK includes a plurality of conductive layers 110 arranged in the Z direction, a plurality of semiconductor pillars 120 extending in the Z direction, and a plurality of gate insulating films 130 provided between the plurality of conductive layers 110 and the plurality of semiconductor pillars 120, respectively.

The conductive layer 110 is a substantially plate-like conductive layer that extends in the X direction. The conductive layer 110 may include a barrier conductive film such as titanium nitride (TiN) and a stacked film of a metal film such as tungsten (W). The conductive layer 110 may also include, for example, a polycrystalline silicon containing an impurity such as phosphorus (P) or boron (B). An insulating layer 101 such as silicon oxide (SiO₂) is provided between the plurality of conductive layers 110 arranged in the Z direction.

Also, of the plurality of conductive layers 110, one or a plurality of conductive layers 110 located at the bottom layer serve as a gate electrode of the source-side select gate line SGS (FIG. 5) and the plurality of source-side select transistors STS (FIG. 5) connected thereto. The plurality of conductive layers 110 are electrically independent of each other for the memory block BLK.

Also, the plurality of conductive layers 110 located thereabove serve as a gate electrode of the word line WL (FIG. 5) and the plurality of memory cells MC (FIG. 5) connected thereto. The plurality of conductive layers 110 are electrically independent of each other for the memory block BLK, respectively.

Also, one or a plurality of conductive layers 110 located thereabove serve as a gate electrode of the drain-side select gate line SGD (FIG. 5) and the plurality of drain-side select transistors STD (FIG. 5) connected thereto. The plurality of conductive layers 110 are smaller in width in the Y direction than the other conductive layers 110.

A semiconductor layer 112 is provided below the plurality of conductive layers 110. The semiconductor layer 112 may include, for example, a polycrystalline silicon containing an impurity such as phosphorus (P) or boron (B). The insulating layer 101 such as silicon oxide (SiO₂) is provided between the semiconductor layer 112 and the conductive layer 110.

The semiconductor layer 112 functions as a source line SL (FIG. 5). For example, the source line SL is commonly provided for all the memory blocks BLK in the memory cell array MCA.

The semiconductor pillars 120 are aligned in a predetermined pattern in the X and Y directions, as illustrated in FIG. 6, for example. The semiconductor pillar 120 functions as a channel region of a plurality of memory cells MC and select transistors STD and STS in one memory string MS (FIG. 5). The semiconductor pillar 120 is, for example, a semiconductor layer such as polycrystalline silicon (Si). The semiconductor pillar 120 has a substantially cylindrical shape, as illustrated in FIG. 6, and an insulating layer 125 such as silicon oxide is provided in the central portion. In addition, the outer peripheral surface of the semiconductor pillar 120 is surrounded by the conductive layer 110 and is opposite the conductive layer 110, respectively.

An impurity region 121 containing an N-type impurity such as phosphorus (P) is provided at the end of the semiconductor pillar 120 on the bit line BL side. The impurity region 121 is connected to the bit line BL via the contacts Ch and Cb.

The gate insulating film 130 has a substantially cylindrical shape that covers the outer peripheral surface of the semiconductor pillar 120. The gate insulating film 130 includes, for example, a tunnel insulating film, a charge storage film, and a block insulating film, which are stacked between the semiconductor pillar 120 and the conductive layer 110. The tunnel insulating film and the block insulating film are insulating films such as, for example, silicon oxide (SiO₂). The charge storage film is, for example, a film capable of storing a charge such as silicon nitride (SiN). The tunnel insulating film, the charge storage film, and the block insulating film have a substantially cylindrical shape and extend in the Z direction along the outer peripheral surface of the semiconductor pillar 120 except for a contact portion between the semiconductor pillar 120 and the semiconductor layer 112.

The gate insulating film 130 may include, for example, a floating gate such as a polycrystalline silicon containing an N-type or a P-type impurity.

The plurality of contacts CC are connected to the plurality of conductive layers 110. The plurality of conductive layers 110 are electrically connected to (e.g., electrically coupled to) the peripheral circuit PC via the plurality of contacts CC. As illustrated in FIG. 6, the plurality of contacts CC extend in the Z direction and are connected to the conductive layer 110 at the lower end. The contact CC may include, for example, a barrier conductive film such as titanium nitride (TiN) and a stacked film of a metal film such as tungsten (W).

The memory cell array MCA may be formed upside down. In other words, the bit line BL may be provided below the plurality of memory blocks BLK. Also, the semiconductor layer 112 may be provided above the plurality of conductive layers 110.

### [Configuration of Peripheral Circuit PC]

The peripheral circuit PC includes a row decoder RD and a sense amplifier SA connected to the memory cell array MCA, and a cache memory CM connected to the sense amplifier, for example, as illustrated in FIG. 4. The peripheral circuit PC also includes a voltage generation circuit VG and a sequencer SQC. In addition, the peripheral circuit PC includes an input/output control circuit I/O, a logic circuit CTR, an address register ADR, a command register CMR, and a status register STR.

The row decoder RD (FIG. 4) includes, for example, a block decoder that decodes a portion of the row address RA included in the address data Add, and a plurality of word line select transistors that conduct the plurality of word lines WL (FIG. 5) in one of the plurality of memory blocks BLK to the plurality of voltage supply lines (not illustrated) in accordance with an output signal of the block decoder.

The sense amplifier SA includes a plurality of sense circuits and a plurality of voltage transfer circuits connected to the plurality of bit lines BL, and a data latch circuit. The sense circuit latches the data of “0” or “1” based on the voltage or current of the bit line BL to the data latch circuit, for example, according to the control signal from the sequencer SQC. The voltage transfer circuit also adjusts the voltage of the bit line BL to “H” or “L” based on the data of “0” or “1” latched to the data latch circuit, for example, according to the control signal from the sequencer SQC. User data Dat in the data latch circuit is output to the input/output control circuit I/O via the cache memory CM and the data bus DB. In addition, the user data Dat output from the input/output control circuit I/O is latched to the data latch circuit in the sense amplifier SA via the data bus DB and the cache memory CM.

The voltage generation circuit VG (FIG. 4) includes, for example, a step-up circuit such as a charge pump circuit and a step-down circuit such as a regulator. The step-up circuit and the step-down circuit are respectively connected to a voltage supply line in which the power supply voltage V_{CC} and the ground voltage V_{SS} are supplied. These voltage supply lines are connected to the pad electrode P, for example, as described with reference to FIGS. 2 and 3. The voltage generation circuit VG generates a plurality of operating voltages to be applied to the bit line BL, the source line SL, the word line WL, and the select gate lines SGD and SGS during the read operation, the write operation, and the erase operation for the memory cell array MCA according to the control signal from the sequencer SQC, for example, and supplies the generated voltage to the bit line BL, the source line SL, the word line WL, and the select gate lines SGD and SGS via the plurality of voltage supply lines. The operating voltage output from the voltage supply line 31 is appropriately adjusted according to the control signal from the sequencer SQC. The voltage generation circuit VG also generates an operating voltage V_{DD} described below and supplies it to each circuit via the voltage supply line.

The sequencer SQC outputs an internal control signal to the row decoder RD, the sense amplifier module SAM, and the voltage generation circuit VG in accordance with the command data Cmd input to the command register CMR. Further, the sequencer SQC outputs the status data Stt indicating the state of the memory die MD to the status register STR as appropriate.

In addition, the sequencer SQC generates a ready/busy signal and outputs it to a terminal RY//BY. The terminal RY//BY goes into an “L” state during the execution of an operation that supplies a voltage to the memory cell array MCA, such as a read operation, a write operation, and an erase operation and goes into an “H” state otherwise. In the period when the terminal RY//BY is in the “L” state (busy period), access to the memory die MD is basically prohibited. In addition, in the period when the terminal RY//BY is in the “H” state (ready period), access to the memory die MD is allowed. The terminal RY//BY is implemented by, for example, the pad electrode P described with reference to FIGS. 2 and 3.

As illustrated in FIG. 4, the address register ADR is connected to the input/output control circuit I/O and stores the address data Add input from the input/output control circuit I/O. The address register ADR includes, for example, a plurality of 8-bit register rows. The register row stores the address data Add corresponding to an internal operation being executed, for example, when the internal operation such as a read operation, a write operation or an erase operation is executed.

The address data Add includes, for example, a column address CA (FIG. 4) and a row address RA (FIG. 4). The row address RA includes, for example, a block address identifying the memory block BLK (FIG. 5), a page address identifying the string unit SU and the word line WL, a plane address identifying the memory cell array MCA, and a chip address identifying the memory die MD.

The command register CMR is connected to the input/output control circuit I/O, and the command data Cmd is provided as input from the input/output control circuit I/O. When the command data Cmd is provided as input to the command register CMR, a control signal is transmitted to the sequencer SQC.

The status register STR is connected to the input/output control circuit I/O and stores the status data Stt to be output to the input/output control circuit I/O. The status register STR includes, for example, a plurality of 8-bit register rows. The register row stores the status data Stt related to an internal operation being executed, for example, when the internal operation such as a read operation, a write operation or an erase operation is executed. In addition, the register row stores, for example, ready/busy information of the memory cell array MCA.

The input/output control circuit I/O includes data signal input/output terminals DQ0 to DQ7, data strobe signal input/output terminals DQS and/DQS, a shift register, and a plurality of input circuits and output circuits connected to the data signal input/output terminals DQ0 to DQ7, respectively. The input circuit is, for example, an input receiver such as a comparator, and the output circuit is, for example, a driver such as an OCD (OffChip Driver) circuit.

Each of the data signal input/output terminals DQ0 to DQ7 and the data strobe signal input/output terminals DQS and/DQS is implemented, for example, by the pad electrode P described with reference to FIGS. 2 and 3. The data input through the data signal input/output terminals DQ0 to DQ7 is provided as input to the cache memory CM, the address register ADR or the command register CMR in response to the internal control signals from the logic circuit CTR. Also, the data output through the data signal input/output terminals DQ0 to DQ7 is output from the cache memory CM or the status register STR in response to the internal control signal from the logic circuit CTR.

The signal input through the data strobe signal input/output terminals DQS and/DQS (for example, data strobe signal and complementary signal thereof) is used at the time of input of data through the data signal input/output terminals DQ0 to DQ7.

The logic circuit CTR includes a plurality of external control terminals/CE, CLE, ALE, /WE, /RE, and RE, and a logic circuit connected to the plurality of external control terminals/CE, CLE, ALE, /WE, /RE, and RE. The logic circuit CTR receives external control signals from the controller die CD via the external control terminals /CE, CLE, ALE, /WE, /RE, and RE and outputs internal control signals to the input/output control circuit I/O accordingly. In the following description, the external control terminal/CE may be referred to as the “chip enable signal input terminal/CE”.

Each of the external control terminals/CE, CLE, ALE, /WE, /RE, and RE is implemented, for example, by the pad electrode P described with reference to FIGS. 2 and 3.

The signal input through the external control terminal/CE (for example, a chip enable signal) is used in selecting the memory die MD. The memory die MD, in which “L” is provided as input to the external control terminal/CE, goes into a state in which input and output of user data Dat, command data Cmd, and address data Add (hereinafter, they may be simply referred to as “data”) are possible. The memory die MD, in which “H” is provided as input to the external control terminal/CE, goes into a state in which data input and output are impossible.

The signal input through the external control terminal CLE (for example, a command latch enable signal) is used when using the command register CMR. When “H” is provided as input to the external control terminal CLE, the data input through the data signal input/output terminals DQ0 to DQ7 is stored in a buffer memory in the input/output control circuit I/O as command data Cmd, and is transferred to the command register CMR.

The signal input through the external control terminal ALE (for example, an address latch enable signal) is used when using the address register ADR. When “H” is provided as input to the external control terminal ALE, the data input through the data signal input/output terminals DQ0 to DQ7 is stored as address data Add in the buffer memory in the input/output control circuit I/O and transferred to the address register ADR.

Note when “L” is provided as input to both the external control terminals CLE and ALE, the data input through the data signal input/output terminals DQ0 to DQ7 is stored in the buffer memory in the input/output control circuit I/O as user data Dat. The user data Dat stored in the buffer memory is transferred to the cache memory CM through the bus DB.

The signal input through the external control terminal/WE (for example, a write enable signal) is used for data input through the data signal input/output terminals DQ0 to DQ7. The data input through the data signal input/output terminals DQ0 to DQ7 is taken into the shift register in the input/output control circuit I/O at the timing of the rise of the voltage of the external control terminal/WE (switching of the input signal).

For data input, the external control terminal /WE may be used, or the data strobe signal input/output terminals DQS and/DQS may be used.

The signal input through the external control terminals/RE and RE (for example, a read enable signal and a complementary signal thereof) is used for data output through the data signal input/output terminals DQ0 to DQ7.

### [Configuration of Chip Enable Signal Detection Circuit]

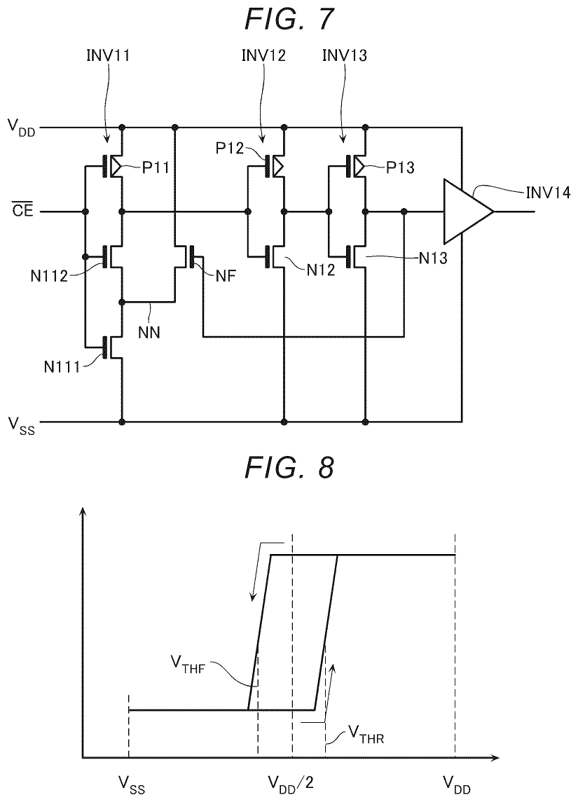

FIG. 7 is a schematic circuit diagram illustrating a configuration of a chip enable signal detection circuit. FIG. 7 illustrates the chip enable signal input terminal/CE and a signal detection circuit in the logic circuit CTR connected to the chip enable signal input terminal/CE. In the present specification, such a signal detection circuit may be referred to as a “chip enable signal detection circuit”.

The chip enable signal detection circuit includes inverter circuits (also referred to herein as “inverter system(s)”) INV11, INV12, INV13, and INV14 provided in the transmission path of the chip enable signal, and a transistor NF, as illustrated in FIG. 7. The inverter circuits INV11, INV12, INV13, and INV14 are CMOS inverter circuits.

The input terminal of the inverter circuit INV11 is connected to the chip enable signal input terminal/CE. The inverter circuit INV11 includes transistors P11, N111, and N112.

The transistor P11 is a P-channel type field effect transistor. A source electrode of the transistor P11 is connected to the voltage supply line through which the operating voltage V_{DD} is supplied. The drain electrode of the transistor P11 is connected to the output terminal of the inverter circuit INV11. The gate electrode of the transistor P11 is connected to the input terminal of the inverter circuit INV11.

The transistor N111 is an N-channel type field effect transistor. The source electrode of the transistor N111 is connected to the voltage supply line through which a ground voltage V_{SS} is supplied.

The drain electrode of the transistor N111 is connected to a node NN. The gate electrode of the transistor N111 is connected to the input terminal of the inverter circuit INV11.

The transistor N112 is an N-channel type field effect transistor. The source electrode of the transistor N112 is connected to the node NN. The drain electrode of the transistor N112 is connected to the output terminal of the inverter circuit INV11.

The gate electrode of the transistor N112 is connected to the input terminal of the inverter circuit INV11.

The input terminal of the inverter circuit INV12 is connected to the output terminal of the inverter circuit INV11. The inverter circuit INV12 includes transistors P12 and N12.

The transistor P12 is a P-channel type field effect transistor. The source electrode of the transistor P12 is connected to the voltage supply line through which the operating voltage V_{DD} is supplied. The drain electrode of the transistor P12 is connected to the output terminal of the inverter circuit INV12. The gate electrode of the transistor P12 is connected to the input terminal of the inverter circuit INV12.

The transistor N12 is an N-channel type field effect transistor. The source electrode of the transistor N12 is connected to the voltage supply line through which the ground voltage V_{SS} is supplied. The drain electrode of the transistor N12 is connected to the output terminal of the inverter circuit INV12. The gate electrode of the transistor N12 is connected to the input terminal of the inverter circuit INV12.

The input terminal of the inverter circuit INV13 is connected to the output terminal of the inverter circuit INV12. The inverter circuit INV13 includes transistors P13 and N13.

The transistor P13 is a P-channel type field effect transistor. The source electrode of the transistor P13 is connected to the voltage supply line through which the operating voltage V_{DD} is supplied. The drain electrode of the transistor P13 is connected to the output terminal of the inverter circuit INV13. The gate electrode of the transistor P13 is connected to the input terminal of the inverter circuit INV13.

The transistor N13 is an N-channel type field effect transistor. The source electrode of the transistor N13 is connected to the voltage supply line through which the ground voltage V_{SS} is supplied. The drain electrode of the transistor N13 is connected to the output terminal of the inverter circuit INV13. The gate electrode of the transistor N13 is connected to the input terminal of the inverter circuit INV13.

The input terminal of the inverter circuit INV14 is connected to the output terminal of the inverter circuit INV13. Although not illustrated, the inverter circuit INV14 includes a P-channel type field effect transistor and an N-channel type field effect transistor connected in series between the voltage supply line through which the operating voltage V_{DD} is supplied and the voltage supply line through which the ground voltage V_{SS} is supplied, in the same manner as the inverter circuits INV12 and INV13. The drain electrodes of these two transistors are connected to the output terminal of the inverter circuit INV14. In addition, the gate electrodes of these two transistors are connected to the input terminal of the inverter circuit INV14.

The transistor NF is an N-channel type field effect transistor. The source electrode of the transistor NF is connected to the node NN. The drain electrode of the transistor NF is connected to the voltage supply line through which the operating voltage V_{DD} is supplied. The output signal of the inverter circuit INV11 (inverted signal of the chip enable signal) is provided as input to the gate electrode of the transistor NF. In the illustrated example, the gate electrode of the transistor NF is connected to the output terminal of the inverter circuit INV13.

### [Transistor Current Capability]

Next, the current capability of a plurality of transistors in the chip enable signal detection circuit will be described. Generally, the current capability can refer to a current capacity related to current conduction, current handling, current drive strength, maximum drain current, saturation current, on-state current, transconductance, and/or any other characteristic affecting the ability of a transistor to conduct or control electrical current. It should be understood that such characteristics may vary based on design parameters, fabrication processes, operating conditions, material properties, circuit topology, and/or any other factor influencing transistor performance. The current capability (e.g., current capacity, drain current capacity, etc.) current handling capacity, of the transistors N111 and N112 is higher than the current capability of other transistors in the chip enable signal detection circuit (transistors P11, P12, N12, P13, N13, and NF, and transistors in the inverter circuit INV14).

For example, the threshold voltage of the transistors N111 and N112 may be lower than the threshold voltage of the other transistors in the chip enable signal detection circuit (transistors P11, P12, N12, P13, N13, and NF, and transistors in the inverter circuit INV14).

For example, the film thickness of the gate insulating film of the transistors N111 and N112 may be smaller than the film thickness of the gate insulating film of the other transistors in the chip enable signal detection circuit (transistors P11, P12, N12, P13, N13, and NF, and the transistor in the inverter circuit INV14).

In this specification, when referring to the threshold voltage of a transistor, the absolute value of the voltage difference between the source electrode and the gate electrode at which an ON/OFF state of the transistor is switched is meant (e.g., at which a transition occurs between the ON state and the OFF state of the second transistor, that results in a transition between the ON state and the OFF state of the second transistor).

For example, the channel width of the transistors N111 and N112 may be larger than the channel width of the other transistors in the chip enable signal detection circuit (transistors P11, P12, N12, P13, N13, and NF, and transistors in the inverter circuit INV14).

In the present specification, each transistor can be replaced by a plurality of transistors connected in parallel. In such a case, the channel width of the transistor is the sum of the channel width of 2 or more transistors connected in parallel.

Further, for example, the channel length of the transistors N111 and N112 may be smaller than the channel length of the other transistors in the chip enable signal detection circuit (transistors P11, P12, N12, P13, N13, and NF, and transistors in the inverter circuit INV14).

In the present specification, each transistor can be replaced by a plurality of transistors connected in series. In such a case, the channel length of the transistor is the sum of the channel length of 2 or more transistors connected in series.

The following description shows an example in which the threshold voltage of the transistors N111 and N112 may be lower than the threshold voltage of the other transistors in the chip enable signal detection circuit (transistors P11, P12, N12, P13, N13, and NF, and transistors in the inverter circuit INV14). Generally, a first transistor described herein can be [ ], the second transistor described herein can be [ ] It should be understood that, generally, a first transistor described herein can be P11, the second transistor described herein can be N111, the third transistor described herein can be N112, the fourth transistor described herein can be NF, the fifth transistor described herein can be P12, the sixth transistor described herein can be N12, and the seventh transistor described herein can be N13, though the transistors are not limited to these specific arrangements and/or implementations.

### [Operation of Chip Enable Signal Detection Circuit]

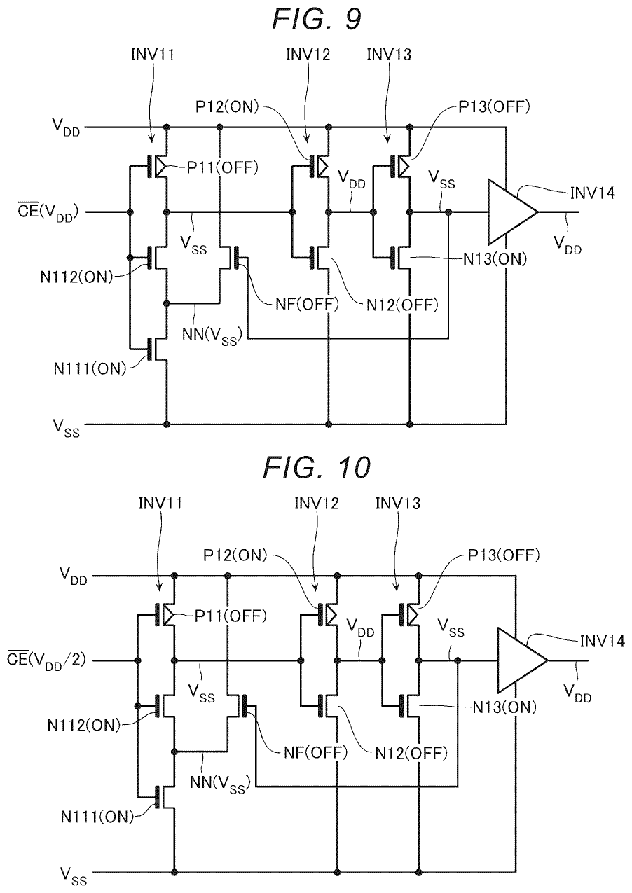

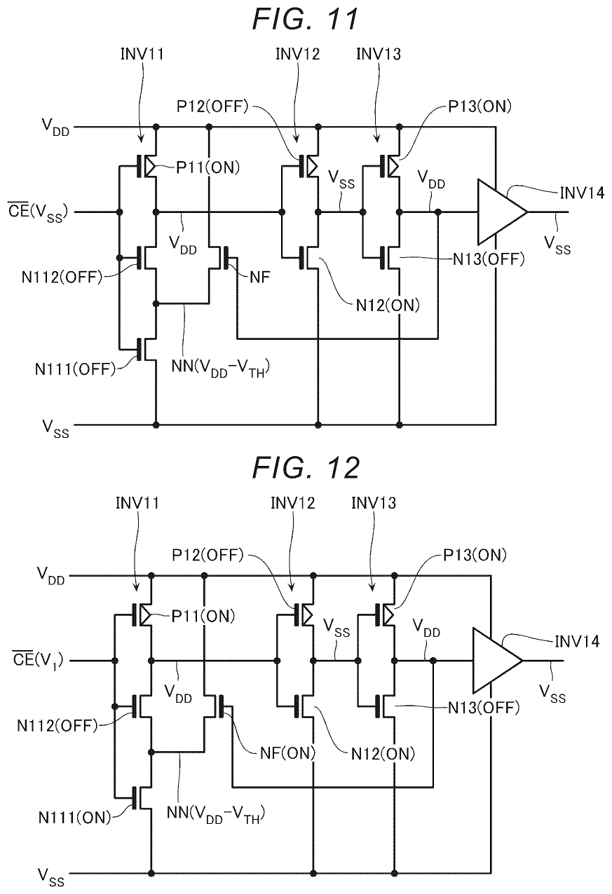

FIG. 8 is a schematic graph illustrating the operation of the chip enable signal detection circuit. The horizontal axis of FIG. 8 represents the voltage of the chip enable signal input terminal /CE, and the vertical axis of FIG. 8 represents the output voltage of the chip enable signal detection circuit (voltage of the output terminal of the inverter circuit INV14). FIGS. 9 to 12 are schematic circuit diagrams illustrating the configuration of the chip enable signal detection circuit. FIG. 9 illustrates the state in which the voltage of the chip enable signal input terminal/CE is the operating voltage V_{DD}. FIG. 10 illustrates a state in which the voltage of the chip enable signal input terminal/CE decreases from the operating voltage V_{DD} to an intermediate voltage V_{DD}/2 between the operating voltage V_{DD} and the ground voltage V_{SS}. FIG. 11 illustrates the state in which the voltage of the chip enable signal input terminal/CE is the ground voltage V_{SS}. FIG. 12 illustrates the state in which the voltage of the chip enable signal input terminal/CE increases from the ground voltage V_{SS} to a threshold voltage V₁ of the transistor N111.

As illustrated in FIG. 9, the voltage of the chip enable signal input terminal/CE is the operating voltage V_{DD}, the transistor P11 is in the OFF state, the transistors N111 and N112 are in the ON state, and the ground voltage V_{SS} is output from the inverter circuit INV11. Further, the transistor P12 is in the ON state, the transistor N12 is in the OFF state, and the operating voltage V_{DD} is output from the inverter circuit INV12. Further, the transistor P13 is in the OFF state, the transistor N13 is in the ON state, and the ground voltage V_{SS} is output from the inverter circuit INV13. In addition, the operating voltage V_{DD} is output from the inverter circuit INV14. In addition, the transistor NF is in the OFF state.

As illustrated in FIG. 10, the output voltage of the inverter circuit INV11 does not switch even if the voltage of the chip enable signal input terminal/CE decreases from the operating voltage V_{DD} to about the intermediate voltage V_{DD}/2 between the operating voltage V_{DD} and the ground voltage V_{SS}. This is because the threshold voltage of the transistor P11 is greater than the threshold voltages of the transistors N111 and N112.

When the voltage of the chip enable signal input terminal/CE further decreases to a threshold voltage V_{THF}, which is lower than the above intermediate voltage V_{DD}/2, the output voltage of the inverter circuit INV11 switches. The threshold voltage V_{THF} is not the threshold voltage of the transistor, but the threshold voltage of the inverter circuit INV11.

As illustrated in FIG. 11, the voltage of the chip enable signal input terminal/CE is the ground voltage V_{SS}, the transistor P11 is in the ON state, the transistors N111 and N112 are in the OFF state, and the operating voltage V_{DD} is output from the inverter circuit INV11. Further, the transistor P12 is in the OFF state, the transistor N12 is in the ON state, and the ground voltage V_{SS} is output from the inverter circuit INV12. Further, the transistor P13 is in the ON state, the transistor N13 is in the OFF state, and the operating voltage V_{DD} is output from the inverter circuit INV13. In addition, the ground voltage V_{SS} is output from the inverter circuit INV14. In addition, the transistor NF is in the ON state, and the node NN is charged to a voltage obtained by subtracting a threshold voltage V_{TH} of the transistor NF from the operating voltage V_{DD}.

As illustrated in FIG. 12, when the voltage of the chip enable signal input terminal/CE increases to the threshold voltage V₁ of the transistor N111, the transistor N111 is in the ON state. Thus, a current path through the transistors NF and N111 is formed between the voltage supply line through which the operating voltage V_{DD} is supplied and the voltage supply line through which the ground voltage V_{SS} is supplied. In this state, since the source-drain current of the transistor N111 is sufficiently small and the transistor NF is in the ON state, the voltage of the node NN is maintained to a voltage obtained by subtracting the threshold voltage V_{TH} of the transistor NF from the operating voltage V_{DD}. As a result, the output voltage of the inverter circuit INV11 is not switched.

As the voltage of the chip enable signal input terminal/CE increases further, the source-drain current of the transistor N111 increases, and the voltage of the node NN gradually decreases. When the voltage difference between the chip enable signal input terminal/CE and the node NN reaches the threshold voltage of the transistor N112 (that is, the voltage of the chip enable signal input terminal/CE reaches a threshold voltage V_{THR} which is higher than the intermediate voltage V_{DD}/2), the transistor N112 is in an ON state, and the output voltage of the inverter circuit INV11 is switched. The threshold voltage V_{THR} is not the threshold voltage of the transistor, but the threshold voltage of the inverter circuit INV11.

### [Effect]

In the chip enable signal detection circuit according to the present embodiment, the threshold voltage V_{THF} when the voltage of the chip enable signal input terminal/CE is reduced is smaller than the threshold voltage V_{THR} when the voltage of the chip enable signal input terminal/CE increases. According to such a configuration, by eliminating the influence of noise, it is possible to achieve a semiconductor device that operates stably.

In addition, the memory die MD generally stays longer in the non-active state than in the active state. Therefore, at the timing when the memory die MD is not in the active state, it is desirable that the leakage current in the chip enable signal detection circuit is small. Since the chip enable signal is a low active signal, it is desirable that the chip enable signal detection circuit has a small leakage current when the chip enable signal is in the H state. For this purpose, for example, as a transistor in the inverter circuit INV11, it is conceivable to select a transistor whose current capability is equal to or lower than a predetermined value.

On the other hand, the chip enable signal is a signal that places the memory die MD in the active state. Therefore, in order to improve the response speed of the memory die MD, when the chip enable signal is switched from the H state to the L state, it is desirable that the output voltage of the chip enable signal detection circuit is also switched from the H state to the L state at high speed. For this purpose, for example, as a transistor in the inverter circuit INV11, it is conceivable to select a transistor whose current capability is equal to or higher than a predetermined value.

However, in the memory die MD as illustrated in this embodiment, for the convenience of the manufacturing process, the type of transistor Tr formed on the upper surface of the semiconductor substrate 100 (FIG. 6) is limited. Therefore, it is necessary to implement each circuit in the peripheral circuit PC with a limited type of transistor Tr, and the transistor Tr with ideal characteristics may not be selected.

Therefore, the chip enable signal detection circuit of this embodiment includes the transistor NF in addition to the inverter circuits INV11, INV12, INV13, and INV14 provided in the chip enable signal transmission path, as described with reference to FIG. 7. Further, the current capability of transistors N111 and N112 is higher than the current capability of other transistors in the chip enable signal detection circuit (transistors P11, P12, N12, P13, N13, and NF, and transistors in the inverter circuit INV14).

According to such a configuration, as described with reference to FIGS. 8 to 12, it is possible to implement a semiconductor device (e.g., a memory device, processor, integrated circuit, logic circuit, signal processing system, storage controller, computing system, and/or any other electronic apparatus and/or system using semiconductor components) that can be suitably operated by lowering the threshold voltage V_{THF} when the voltage of the chip enable signal input terminal /CE is reduced than the threshold voltage V_{THR} when the voltage of the chip enable signal input terminal /CE increases.

Further, since the current capability of the transistor P11 is lower than the current capability of the transistors N111 and N112, it is possible to reduce the leakage current in the chip enable signal detection circuit at a timing when the memory die MD is not in the active state, and to provide a semiconductor device with low power consumption.

In addition, since the transistor NF is in the OFF state when the voltage of the chip enable signal input terminal/CE is the operating voltage V_{DD}, a high response speed when the chip enable signal is switched from the H state to the L state is achieved, and it is possible to provide a semiconductor device that operates suitably.

### Second Embodiment

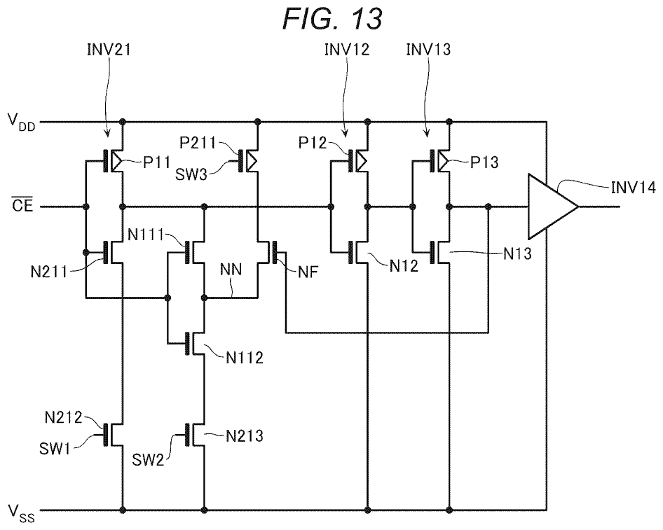

Next, a semiconductor device according to a second embodiment will be described with reference to FIG. 13. FIG. 13 is a schematic circuit diagram illustrating the configuration of the chip enable signal detection circuit according to the second embodiment. In the following description, the same reference numerals are denoted to the portions similar to those in the first embodiment, and the description thereof is omitted.

The semiconductor device according to the second embodiment is basically configured in the same manner as the semiconductor device according to the first embodiment. However, the chip enable signal detection circuit according to the second embodiment is different from the chip enable signal detection circuit according to the first embodiment. The chip enable signal detection circuit according to the second embodiment is basically configured in the same manner as the chip enable signal detection circuit according to the first embodiment.

However, the chip enable signal detection circuit according to the second embodiment includes an inverter circuit INV21 instead of the inverter circuit INV11. Further, the chip enable signal detection circuit according to the second embodiment includes switch transistors N212, N213, and P211.

The inverter circuit INV21 is basically configured in the same manner as the inverter circuit INV11. However, the inverter circuit INV21 further includes a transistor N211.

The transistor N211 is an N-channel type field effect transistor. The source electrode of the transistor N211 is connected to the voltage supply line through which the ground voltage V_{SS} is supplied. The drain electrode of the transistor N211 is connected to the output terminal of the inverter circuit INV21. The gate electrode of the transistor N211 is connected to the input terminal of the inverter circuit INV21.

Note that the current capability of the transistors N111 and N112 is higher than the current capability of the transistor N211.

The switch transistor N212 is an N-channel type field effect transistor. The switch transistor N212 is electrically connected between the transistor N211 and the voltage supply line through which the ground voltage V_{SS} is supplied. That is, the source electrode of the switch transistor N212 is connected to the voltage supply line through which the ground voltage V_{SS} is supplied. Further, the drain electrode of the switch transistor N212 is connected to the source electrode of the transistor N211. The gate electrode of the switch transistor N212 is connected to the signal line SW1.

The switch transistor N213 is an N-channel type field effect transistor. The switch transistor N213 is electrically connected between the transistor N112 and the voltage supply line through which the ground voltage V_{SS} is supplied. That is, the source electrode of the switch transistor N213 is connected to the voltage supply line through which the ground voltage V_{SS} is supplied. Further, the drain electrode of the switch transistor N213 is connected to the source electrode of the transistor N112. The gate electrode of the switch transistor N213 is connected to the signal line SW2.

The switch transistor P211 is a P-channel type field effect transistor. The switch transistor P211 is electrically connected between the transistor NF and the voltage supply line through which the operating voltage V_{DD} is supplied. That is, the source electrode of the switch transistor P211 is connected to the voltage supply line through which the operating voltage V_{DD} is supplied. Further, the drain electrode of the switch transistor P211 is connected to the drain electrode of the transistor NF. The gate electrode of the switch transistor P211 is connected to the signal line SW3.

The chip enable signal detection circuit according to the second embodiment can be operated in 2 different modes.

In the first operation mode, the signal of the signal line SW1 is set to the L state, the signal of the signal line SW2 is set to the H state, and the signal of the signal line SW3 is set to the L state. Thus, the chip enable signal detection circuit according to the second embodiment operates in the same manner as the chip enable signal detection circuit according to the first embodiment.

In the second operation mode, the signal of the signal line SW1 is set to the H state, the signal of the signal line SW2 is set to the L state, and the signal of the signal line SW3 is set to the H state. Thus, the chip enable signal detection circuit according to the second embodiment operates in a different manner from the chip enable signal detection circuit according to the first embodiment. Specifically, the threshold voltage of the inverter circuit INV21 when the voltage of the chip enable signal input terminal/CE is reduced matches the threshold voltage of the inverter circuit INV21 when the voltage of the chip enable signal input terminal /CE is increased. At this time, the threshold voltage of the inverter circuit INV21 is about the intermediate voltage V_{DD}/2 between the operating voltage V_{DD} and the ground voltage V_{SS}.

### Third Embodiment

In the first embodiment and the second embodiment, an example in which the chip enable signal is a low active signal was described. However, even if the chip enable signal is a high active signal, it is possible to provide a semiconductor device that consumes low power and operates suitably, by adopting a configuration similar to the first embodiment and the second embodiment. For this purpose, for example, in the chip enable signal detection circuit according to the first embodiment or the second embodiment, the N-channel type field effect transistor and the P-channel type field effect transistor may be replaced, and the voltage supply line through which the operating voltage V_{DD} is supplied and the voltage supply line through which the ground voltage V_{SS} is supplied may be interchanged. Hereinafter, as the semiconductor device according to the third embodiment, such an example will be described.

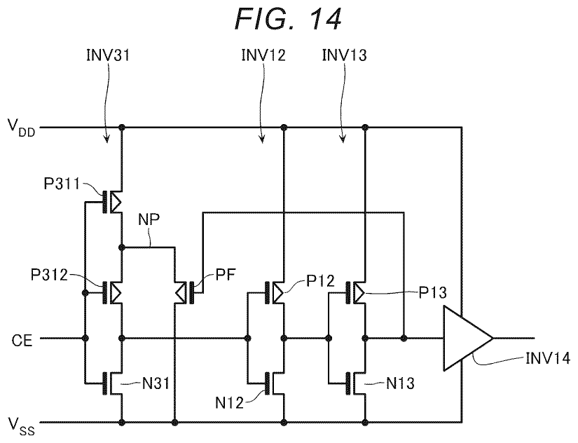

FIG. 14 is a schematic circuit diagram illustrating the configuration of the chip enable signal detection circuit according to the third embodiment. In the following description, the same reference numerals are denoted to the portions similar to those in the first embodiment, and the description thereof is omitted.

The semiconductor device according to the third embodiment is basically configured in the same manner as the semiconductor device according to the first embodiment. However, the chip enable signal according to the third embodiment is not a low active signal, but a high active signal. Also, the chip enable signal detection circuit according to the third embodiment is different from the chip enable signal detection circuit according to the first embodiment. The chip enable signal detection circuit according to the third embodiment is basically configured in the same manner as the chip enable signal detection circuit according to the first embodiment.

However, the chip enable signal detection circuit according to the third embodiment includes an inverter circuit INV31 and a transistor PF instead of the inverter circuit INV11 and the transistor NF.

The inverter circuit INV31 is a CMOS inverter circuit. The input terminal of the inverter circuit INV31 is connected to the chip enable signal input terminal CE. The inverter circuit INV31 includes transistors P311, P312, and N31.

The transistor P311 is a P-channel type field effect transistor. The source electrode of the transistor P311 is connected to the voltage supply line through which the operating voltage V_{DD} is supplied. The drain electrode of the transistor P311 is connected to a node NP. The gate electrode of the transistor P311 is connected to the input terminal of the inverter circuit INV31.

The transistor P312 is a P-channel type field effect transistor. The source electrode of the transistor P312 is connected to the node NP. The drain electrode of the transistor P312 is connected to the output terminal of the inverter circuit INV31. The gate electrode of the transistor P312 is connected to the input terminal of the inverter circuit INV31.

The transistor N31 is an N-channel type field effect transistor. The source electrode of the transistor N31 is connected to the voltage supply line through which the ground voltage V_{SS} is supplied. The drain electrode of the transistor N31 is connected to the output terminal of the inverter circuit INV31. The gate electrode of the transistor N31 is connected to the input terminal of the inverter circuit INV31.

The transistor PF is a P-channel type field effect transistor. The source electrode of the transistor PF is connected to the node NP. The drain electrode of the transistor PF is connected to the voltage supply line through which the ground voltage V_{SS} is supplied. The output signal of the inverter circuit INV31 (inverted signal of the chip enable signal) is provided as input to the gate electrode of the transistor PF. In the illustrated example, the gate electrode of the transistor PF is connected to the output terminal of the inverter circuit INV13.

The current capability of transistors P311 and P312 is higher than the current capability of other transistors in the chip enable signal detection circuit (transistors N31, P12, N12, P13, N13, and PF, and transistors in the inverter circuit INV14).

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a signal input terminal configured to input a signal;
a first transistor of a first conductivity type comprising a source electrode electrically connected to a first voltage supply line, a drain electrode electrically connected to a first node, and a gate electrode electrically connected to the signal input terminal;
a second transistor of a second conductivity type comprising a source electrode electrically connected to a second voltage supply line, a drain electrode electrically connected to a second node, and a gate electrode electrically connected to the signal input terminal;
a third transistor of the second conductivity type comprising a source electrode electrically connected to the second node, a drain electrode electrically connected to the first node, and a gate electrode electrically connected to the signal input terminal; and
a fourth transistor of the second conductivity type comprising a source electrode electrically connected to the second node, a drain electrode electrically connected to the first voltage supply line, and a gate electrode to which a signal of the first node is provided as input;
wherein a current capacity of the second transistor and a current capacity of the third transistor are higher than a current capacity of the first transistor.

2. The semiconductor device of claim 1, wherein:
a threshold voltage of the second transistor and a threshold voltage of the third transistor are smaller than a threshold voltage of the first transistor;
the threshold voltage of the first transistor is an absolute value of a voltage difference between the source electrode and the gate electrode at which an ON/OFF state of the first transistor is switched;
the threshold voltage of the second transistor is an absolute value of a voltage difference between the source electrode and the gate electrode at which an ON/OFF state of the second transistor is switched; and
the threshold voltage of the third transistor is an absolute value of a voltage difference between the source electrode and the gate electrode at which an ON/OFF state of the third transistor is switched.

3. The semiconductor device of claim 1, wherein a film thickness of a gate insulating film of the second transistor and a film thickness of a gate insulating film of the third transistor are smaller than a film thickness of a gate insulating film of the first transistor.

4. The semiconductor device of claim 1, wherein a channel width of the second transistor and a channel width of the third transistor are greater than a channel width of the first transistor.

5. The semiconductor device of claim 1, wherein a channel length of the second transistor and a channel length of the third transistor are smaller than a channel length of the first transistor.

6. The semiconductor device of claim 1, further comprising:
a first inverter circuit comprising an input terminal electrically connected to the first node and an output terminal electrically connected to a third node; and
a second inverter circuit comprising an input terminal electrically connected to the third node and an output terminal electrically connected to the gate electrode of the fourth transistor.

7. The semiconductor device of claim 6, wherein the first inverter circuit comprises:
a fifth transistor of the first conductivity type comprising a source electrode electrically connected to the first voltage supply line, a drain electrode electrically connected to the third node, and a gate electrode electrically connected to the first node; and
a sixth transistor of the second conductivity type comprising a source electrode electrically connected to the second voltage supply line, a drain electrode electrically connected to the third node, and a gate electrode electrically connected to the first node;
wherein the current capacity of the second transistor and the current capacity of the third transistor are higher than the current capacity of the sixth transistor.

8. The semiconductor device of claim 1, further comprising:
a seventh transistor of the second conductivity type comprising a source electrode electrically connected to the second voltage supply line, a drain electrode electrically connected to the first node, and a gate electrode electrically connected to the signal input terminal;
a first switch transistor electrically connected between the seventh transistor and the second voltage supply line;
a second switch transistor electrically connected between the second transistor and the second voltage supply line; and
a third switch transistor electrically connected between the fourth transistor and the first voltage supply line.

9. The semiconductor device of claim 1, wherein:
a voltage supplied to the first voltage supply line is higher than a voltage supplied to the second voltage supply line;
the transistors of the first conductivity type are P-channel type field effect transistors; and
the transistors of the second conductivity type are N-channel type field effect transistors.

10. The semiconductor device of claim 1, wherein a voltage supplied to the first voltage supply line is lower than a voltage supplied to the second voltage supply line;
wherein the transistors of the first conductivity type are N-channel type field effect transistors;
wherein the transistors of the second conductivity type are P-channel type field effect transistors.

11. The semiconductor device of claim 1, further comprising:
a NAND flash memory.

12. A semiconductor device, comprising:
a signal input terminal configured to input a signal;
a first transistor of a first conductivity type comprising a source electrode electrically connected to a first voltage supply line, a drain electrode electrically connected to a first node, and a gate electrode electrically connected to the signal input terminal;
a second transistor of a second conductivity type comprising a source electrode electrically connected to a second voltage supply line, a drain electrode electrically connected to a second node, and a gate electrode electrically connected to the signal input terminal;
a third transistor of the second conductivity type comprising a source electrode electrically connected to the second node, a drain electrode electrically connected to the first node, and a gate electrode electrically connected to the signal input terminal;
a fourth transistor of the second conductivity type comprising a source electrode electrically connected to the second node, a drain electrode electrically connected to the first voltage supply line, and a gate electrode to which a signal of the first node is provided as input;
a fifth transistor of the first conductivity type comprising a source electrode electrically connected to the first voltage supply line, a drain electrode electrically connected to a third node, and a gate electrode electrically connected to the first node; and
a sixth transistor of the second conductivity type comprising a source electrode electrically connected to the second voltage supply line, a drain electrode electrically connected to the third node, and a gate electrode electrically connected to the first node;
wherein a current capacity of the second transistor and a current capacity of the third transistor are higher than a current capacity of the sixth transistor.

13. The semiconductor device of claim 12, wherein:
a threshold voltage of the second transistor and a threshold voltage of the third transistor are smaller than a threshold voltage of the sixth transistor;
the threshold voltage of the second transistor is an absolute value of a voltage difference between the source electrode and the gate electrode at which an ON/OFF state of the second transistor is switched;
the threshold voltage of the third transistor is an absolute value of a voltage difference between the source electrode and the gate electrode at which an ON/OFF state of the third transistor is switched; and
the threshold voltage of the sixth transistor is an absolute value of a voltage difference between the source electrode and the gate electrode at which an ON/OFF state of the first transistor is switched.

14. The semiconductor device of claim 12, wherein a film thickness of a gate insulating film of the second transistor and a film thickness of a gate insulating film of the third transistor are smaller than a film thickness of a gate insulating film of the sixth transistor.

15. The semiconductor device of claim 12, further comprising:
a seventh transistor of the second conductivity type comprising a source electrode electrically connected to the second voltage supply line, a drain electrode electrically connected to the first node, and a gate electrode electrically connected to the signal input terminal;
a first switch transistor electrically connected between the seventh transistor and the second voltage supply line;
a second switch transistor electrically connected between the second transistor and the second voltage supply line; and
a third switch transistor electrically connected between the fourth transistor and the first voltage supply line.

16. A semiconductor device, comprising:
a signal input terminal configured to input a signal;
a first transistor of a first conductivity type comprising a source electrode electrically connected to a first voltage supply line, a drain electrode electrically connected to a first node, and a gate electrode electrically connected to the signal input terminal;
a second transistor of a second conductivity type comprising a source electrode electrically connected to a second voltage supply line, a drain electrode electrically connected to a second node, and a gate electrode electrically connected to the signal input terminal;
a third transistor of the second conductivity type comprising a source electrode electrically connected to the second node, a drain electrode electrically connected to the first node, and a gate electrode electrically connected to the signal input terminal; and
a fourth transistor of the second conductivity type comprising a source electrode electrically connected to the second node, a drain electrode electrically connected to the first voltage supply line, and a gate electrode to which a signal of the first node is provided as input;
wherein a film thickness of a gate insulating film of the second transistor and a film thickness of a gate insulating film of the third transistor are smaller than a film thickness of a gate insulating film of the first transistor.

17. The semiconductor device of claim 16, further comprising:
a first inverter circuit comprising an input terminal electrically connected to the first node and an output terminal electrically connected to a third node; and
a second inverter circuit comprising an input terminal electrically connected to the third node and an output terminal electrically connected to the gate electrode of the fourth transistor.

18. The semiconductor device of claim 17, wherein the first inverter circuit comprises:
a fifth transistor of the first conductivity type comprising a source electrode electrically connected to the first voltage supply line, a drain electrode electrically connected to the third node, and a gate electrode electrically connected to the first node; and
a sixth transistor of the second conductivity type comprising a source electrode electrically connected to the second voltage supply line, a drain electrode electrically connected to the third node, and a gate electrode electrically connected to the first node, wherein a film thickness of a gate insulating film of the second transistor and a film thickness of a gate insulating film of the third transistor are smaller than a film thickness of a gate insulating film of the sixth transistor.

19. The semiconductor device of claim 16, further comprising:
a seventh transistor of the second conductivity type comprising a source electrode electrically connected to the second voltage supply line, a drain electrode electrically connected to the first node, and a gate electrode electrically connected to the signal input terminal;
a first switch transistor electrically connected between the seventh transistor and the second voltage supply line;
a second switch transistor electrically connected between the second transistor and the second voltage supply line; and
a third switch transistor electrically connected between the fourth transistor and the first voltage supply line.
